(19) United States
(12) Patent Application Publication
(10) Pub. No.: US 2023/0040495 A1
(43) Pub. Date: Feb. 9, 2023

(54) RETENTION OF HIGH-PRESSURE-INDUCED/ENHANCED HIGH TC SUPERCONDUCTING AND NON-SUPERCONDUCTING PHASES AT AMBIENT PRESSURE

(71) Applicant: UNIVERSITY OF HOUSTON SYSTEM, Houston, TX (US)

(72) Inventors: Ching-Wu CHU, Houston, TX (US); Liangzi DENG, Pearland, TX (US); Zheng WU, Missouri City, TX (US)

(21) Appl. No.: 17/883,534

(22) Filed: Aug. 8, 2022

Related U.S. Application Data
(60) Provisional application No. 63/230,389, filed on Aug. 6, 2021.

(51) Int. Cl. H01F 6/02

(52) U.S. Cl. CPC H01F 6/02

(57) ABSTRACT

A pressure-quench techniques at chosen pressures and temperatures to lock in the high-pressure-induced superconducting phase and/or non-superconducting phase in high-temperature superconductors (HTS) and room-temperature superconductors (RTS) at ambient pressure are disclosed. The techniques remove the formidable obstacle to the ubiquitous practical application of HTS and RTS. The technique successfully retain the high-pressure-induced/-enhanced high Tc and/or non-superconducting properties of HTS or RTS.

### CROSS REFERENCE TO RELATED APPLICATION(S)

This application claims priority to U.S. provisional patent application No. 63/230,389, filed on Aug. 6, 2021, which is hereby incorporated herein by reference in its entirety.

### GOVERNMENT SPONSORSHIP

This invention was made with government support under FA9550-15-1-0236 and FA9550-20-1-0068 awarded by the U.S. Air Force Office of Scientific Research. The Government has certain rights in the invention.

### FIELD

The embodiments disclosed herein are in the field of superconductors. More particularly, the embodiments disclosed herein relate to the retention of a high-pressure-induced superconducting phase or non-superconducting phase in a high-temperature superconductor (HTS) or a room-temperature superconductor (RTS), at ambient pressure.

### BACKGROUND

The desire to raise the superconducting-transition temperature (T_{c}) has been the driving force for the long-sustained effort in superconductivity research. Recent progress in hydrides with T_{c}s up to 287 K under the pressure of 267 GPa has heralded a new era of room-temperature superconductivity (RTS) with immense technological promise. Indeed, RTS will lift the temperature barrier for the ubiquitous application of superconductivity. Unfortunately, formidable pressure is required to attain such high T_{c}s. Therefore, there is a need to retain the superconducting phase or non-superconducting phase in a HTS or a RTS, at ambient pressure.

Thus, it is desirable to provide a superconductor and method of making the same that are able to overcome the above disadvantages.

These and other advantages of the present invention will become more fully apparent from the detailed description of the invention herein below.

### SUMMARY

Embodiments are directed to a method for retaining a high-pressure-induced superconducting or non-superconducting phase in a high-temperature superconductor HTS (with a T_{c} between 20 K and 160 K) or a RTS (with a T_{c} above 160 K), at ambient or atmospheric pressure. In other words, an embodiment retains (either) a superconducting or non-superconducting phase in a HTS. Or, another embodiment retains (either) a superconducting or non-superconducting phase in a RTS. And any/all of the above phase scenarios are being retained at ambient pressure. The method includes: generating a superconducting or non-superconducting phase in a HTS or RTS by applying pressure at room temperature thereby producing a superconducting phase with a particular T_{c} or a non-superconducting phase in the HTS or RTS; pressure-quenching the HTS or RTS from the generating step while under the pressure at room temperature, by subsequently removing the pressure to achieve ambient pressure at a temperature lower than 300 K, while maintaining the superconducting phase with the particular T_{c} or the non-superconducting phase in the HTS or RTS; and retaining the superconducting or non-superconducting phase in the HTS or RTS while maintaining the superconducting phase with the particular T_{c} or the non-superconducting phase in the HTS or RTS, at ambient pressure, subsequent to the pressure-quenching step.

Embodiments are also directed to a HTS or a RTS having a superconducting phase with a particular T_{c} or non-superconducting phase in the HTS or RTS induced via an applied pressure at room temperature and retained at ambient pressure.

### BRIEF DESCRIPTION OF THE DRAWINGS

The foregoing summary, as well as the following detailed description, will be better understood when read in conjunction with the appended drawings. For the purpose of illustration only, there are shown in the drawings certain embodiments. It's understood, however, that the inventive concepts disclosed herein are not limited to the precise arrangements and instrumentalities shown in the figures.

FIG. 1A is a schematic diagram illustrating Gibbs free energy and the energy barrier between the metastable and stable states.

FIG. 1B is a schematic diagram illustrating the sequence of main experimental steps, in accordance with an example of an embodiment.

FIG. 2A is a plot illustrating T_{c} as a function of P_{A} or P_{Q} for single-crystalline FeSe. High-pressure T_{c} (P_{A}) at P_{A} (squares), and T_{c} (P_{Q}) at ambient pressure for FeSe PQed at P_{Q} and T_{Q}=4.2 K (circles) and T_{Q}=77 K (diamonds), respectively.

FIG. 2B is a plan view illustrating a 2.238 mm diagonal FeSe single crystal superconductor which is used for preparing smaller superconductor samples that pressure is applied to, in accordance with an example of an embodiment. Alternatively, the superconductors that pressure is applied to can be in polycrystal form.

FIGS. 3A-3F are plots illustrating pressure-quenching of the single-crystalline FeSe (shown, for example, in FIG. 2B). R(T)/R(70 K) or R(T)/R(50 K) under P_{A} and at ambient pressure before and after PQ.

FIG. 4 is a plot illustrating T_{c} as a function of P_{A} or P_{Q} for single-crystalline Cu-doped FeSe. T_{c} (P_{A}) at P_{A} (squares); and at T_{c} (P_{Q}) at ambient pressure for the samples PQed at P_{Q} and T_{Q}=4.2 K (circles) and at T_{Q}=77 K (diamonds), respectively.

FIGS. 5A-5F are plots illustrating pressure-quenching of the single-crystalline Cu-doped FeSe. R(T)/R(50 K) under P_{A} and at ambient pressure after PQ, and testing the stability of the PQed phases.

FIGS. 6A-6D are plots illustrating calculated energy barriers between different phases of FeSe.

FIG. 7 is a plot illustrating R(P_{A})/R(0) of FeSe and Cu-doped FeSe single crystals at 300 K during pressure cycling. Dashed lines represent preliminary phase boundaries for FeSe. Numbers denote the sequential order of the experimental runs at different pressures.

FIGS. 8A-8B are plots illustrating resistance as a function of temperature for FeSe and Cu-doped FeSe single crystals, respectively.

FIG. 9 is a plot illustrating T_{c} as a function of P_{A} or P_{Q} for single-crystalline Cu-doped FeSe. High-pressure T_{c} (P_{A}) at P_{A} (squares); and T_{c} (P_{Q}) at ambient pressure for Cu-doped FeSe sample PQed at P_{Q} and T_{Q}=77 K (diamonds).

FIG. 10 is a flowchart illustrating an embodiment of a method of fabricating a superconductor. Included are the sequential PQP steps to obtain, test, and characterize the high T_{c} phase at ambient.

FIG. 11 is a plot illustrating record T_{c} as a function of time.

FIG. 12 is a plot illustrating Gibbs free energy and the energy barrier between a superconducting (SC) state with a higher T_{c} and a non-SC state or a SC state with a lower T_{c}, demonstrating an approach to capture the “supercool” state via pressure-quench.

FIG. 13 is a plot illustrating pressure dependence of resistance at room temperature for four different structure phases I-IV of Sb: I—rhombohedral phase; II—monoclinic host-guest phase; III—tetragonal host-guest phase; and IV—bcc phase.

FIGS. 14A-14B are plots illustrating the onset T_{c}s at different pressures for four different phases I-IV of Sb.

FIGS. 15A-15C are plots illustrating resistance versus temperature for Phase II of Sb (and IV in FIG. 15C).

FIGS. 16A-16B are plots illustrating resistance versus temperature for Phase IV of Sb.

### DETAILED DESCRIPTION

It is to be understood that the figures and descriptions of the present invention may have been simplified to illustrate elements that are relevant for a clear understanding of the present embodiments, while eliminating, for purposes of clarity, other elements found in a typical superconductor or typical method of fabricating a superconductor. Those of ordinary skill in the art will recognize that other elements may be desirable and/or required in order to implement the present embodiments. However, because such elements are well known in the art, and because they do not facilitate a better understanding of the present embodiments, a discussion of such elements is not provided herein. It is also to be understood that the drawings included herewith only provide diagrammatic representations of the presently preferred structures of the present invention and that structures falling within the scope of the present embodiments may include structures different than those shown in the drawings. Reference will now be made to the drawings wherein like structures are provided with like reference designations.

Before explaining at least one embodiment in detail, it should be understood that the concepts set forth herein are not limited in their application to the construction details or component arrangements set forth in the following description or illustrated in the drawings. It should also be understood that the phraseology and terminology employed herein are merely for descriptive purposes and should not be considered limiting.

It should further be understood that any one of the described features may be used separately or in combination with other features. Other embodiments of devices, systems, methods, features, and advantages described herein will be or become apparent to one with skill in the art upon examining the drawings and the detailed description herein. It's intended that all such additional devices, systems, methods, features, and advantages be protected by the accompanying claims.

For purposes of this disclosure, the term “ambient” refers to “ambient pressure” or “atmospheric pressure”, i.e., meaning without extra or additional pressure applied. Notwithstanding the particular superconductor composition used, ambient may generally fall within the range of 0.0001 GPa-0.1 GPa.

For purposes of this disclosure, the phrases “room temperature” or “room T_{c}” may be used interchangeably and refer to a temperature above 160 K.

For purposes of this disclosure, the phrases “high temperature” or “high T_{c}” may be used interchangeably and refer to a temperature in the range of 30 K-160 K.

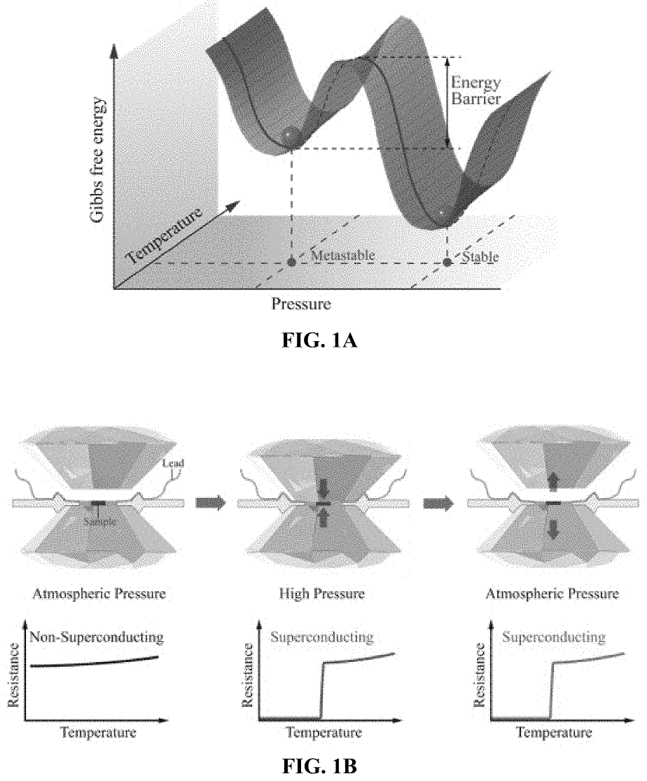

FIG. 1A is a schematic diagram illustrating Gibbs free energy and the energy barrier between the metastable and stable states.

FIG. 1B is a schematic diagram illustrating the sequence of main experimental steps, in accordance with an example of an embodiment.

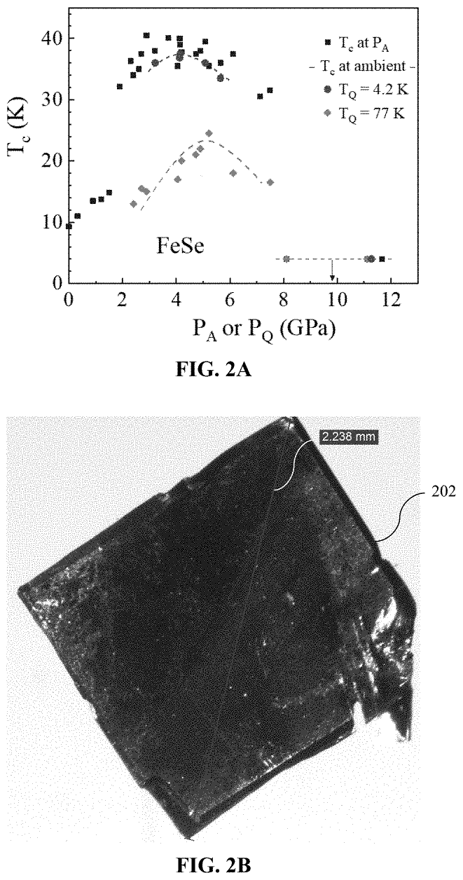

FIG. 2A is a plot illustrating T_{c} as a function of P_{A} or P_{Q} for single-crystalline FeSe. High-pressure T_{c} (P_{A}) at P_{A} (squares), and T_{c} (P_{Q}) at ambient pressure for FeSe PQed at P_{Q} and T_{Q}=4.2 K (circles) and T_{Q}=77 K (diamonds), respectively.

FIG. 2B is a plan view illustrating a 2.238 mm diameter FeSe single crystal superconductor 202 which is used for preparing smaller superconductor samples (having a diagonal in the range of 0.1 mm-0.2 mm) that pressure is applied to, in accordance with an example of an embodiment. Alternatively, the superconductors that pressure is applied to can be in polycrystal form.

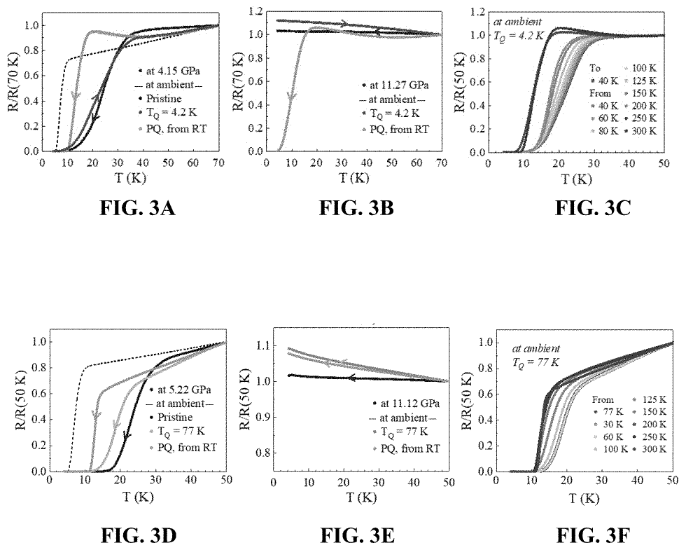

FIGS. 3A-3F are plots illustrating pressure-quenching of the single-crystalline FeSe (shown, for example, in FIG. 2B). R(T)/R(70 K) or R(T)/R(50 K) under P_{A} and at ambient pressure before and after PQ:
at P_{A}=4.15 GPa (blue), and at ambient pressure before PQ on cooling (black), after PQ at 4.15 GPa and 4.2 K on warming (red), and on cooling after warming to 300 K (orange), as shown in FIG. 3A;
at P_{A}=11.27 GPa (blue), and at ambient pressure after PQ at 11.27 GPa and 4.2 K on warming (red) and on cooling after warming to 300 K (orange), as shown in FIG. 3B;
after PQ at 4.13 GPa and 4.2 K, warmed to 40 K and sequentially cooled from different temperatures between 40 K and 300 K, as shown in FIG. 3C;
at P_{A}=5.22 GPa (blue), and at ambient pressure before PQ on cooling (black), after PQ at 5.22 GPa and 77 K on cooling (green) and on cooling after warming to 300 K (orange), as shown in FIG. 3D;
at P_{A}=11.12 GPa (blue), and at ambient pressure after PQ at 11.12 GPa and 77 K on cooling (green) and on cooling after warming to 300 K (orange), as shown in FIG. 3E; and
after PQ at 5.22 GPa and 77 K sequentially cooled from different temperatures between 77 K and 300 K, as shown in FIG. 3F.

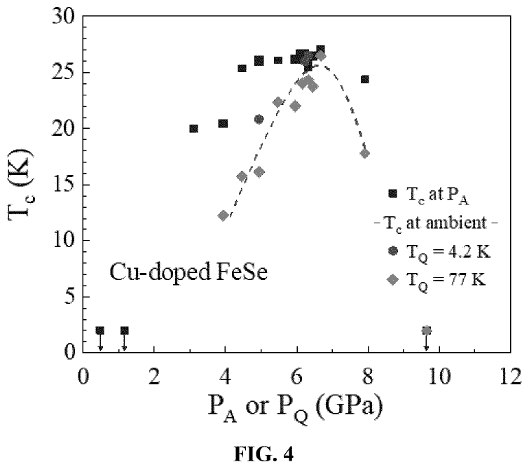

FIG. 4 is a plot illustrating T_{c} as a function of P_{A} or P_{Q} for single-crystalline Cu-doped FeSe. T_{c} (P_{A}) at P_{A} (squares); and at T_{c} (P_{Q}) at ambient pressure for the samples PQed at P_{Q} and T_{Q}=4.2 K (circles) and at T_{Q}=77 K (diamonds), respectively.

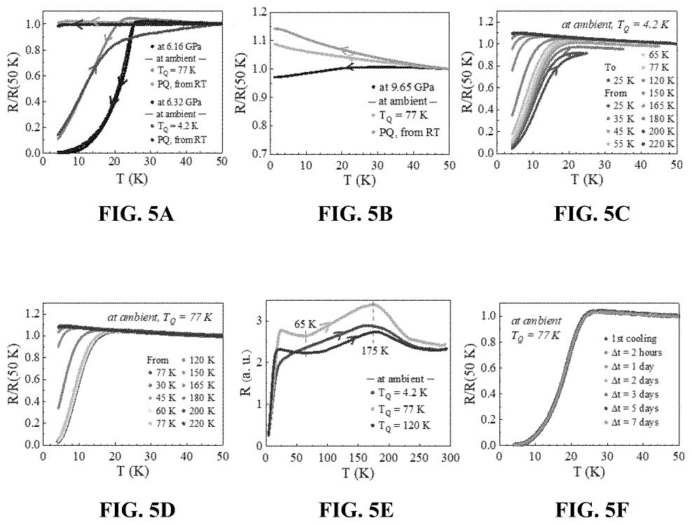

FIGS. 5A-5F are plots illustrating pressure-quenching of the single-crystalline Cu-doped FeSe. R(T)/R(50 K) under P_{A} and at ambient pressure after PQ, and testing the stability of the PQed phases:
at P_{A}=6.16 GPa (navy) and 6.32 GPa (blue), and at ambient pressure after PQ at 6.16 GPa and 77 K (green) and at 6.32 GPa and 4.2 K (red), and on cooling after warming to 300 K (orange and brown), as shown in FIG. 5A;
at P_{A}=9.65 GPa (blue), at ambient pressure after PQ at 9.65 GPa and 77 K (green), and on cooling after warming to 300 K (orange), as shown in FIG. 5B;
at ambient pressure after PQ at 6.08 GPa and 4.2 K, warmed to 25 K and sequentially cooled from different temperatures between 25 K and 220 K, as shown in FIG. 5C;
at ambient pressure after PQ at 5.95 GPa and 77 K sequentially cooled from different temperatures between 77 K and 220 K, as shown in FIG. 5D;
R(T) at ambient pressure for the same sample subjected to different PQ conditions: P_{Q}=6.31 GPa and T_{Q}=4.2 K (red), P_{Q}=6.16 GPa and T_{Q}=77 K (green), and P_{Q}=6.51 GPa and T_{Q}=120 K (purple), as shown in FIG. 5E; and
repeated thermal cycling at ambient pressure from 50 K for the sample PQed at 6.67 GPa and 77 K, as shown in FIG. 5F.

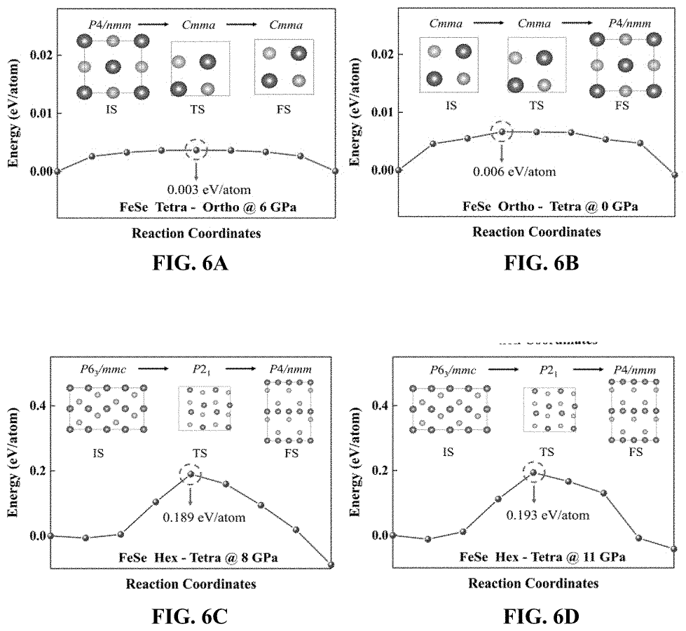

FIGS. 6A-6D are plots illustrating calculated energy barriers between different phases of FeSe, in which:
the calculated energy barrier from the tetragonal phase to the orthorhombic phase at 6 GPa is shown in FIG. 6A;
the calculated energy barrier from the orthorhombic phase to the tetragonal phase at 0 GPa is shown in FIG. 6B;
the calculated energy barrier from the hexagonal phase to the tetragonal phase at 8 GPa is shown in FIG. 6C; and
the calculated energy barrier from the hexagonal phase to the tetragonal phase at 11 GPa is shown in FIG. 6D.

The insets illustrated in FIGS. 6A-6D show the side views of corresponding structures including the initial state (IS), the transition state (TS), and the final state (FS) along the c axis. The energy barrier was calculated through the solid-state nudged elastic band method in which seven images were used. The arrows show the transition state that is the image with the highest energy and the estimated energy barrier. The green and brown spheres represent elemental Se and Fe, respectively.

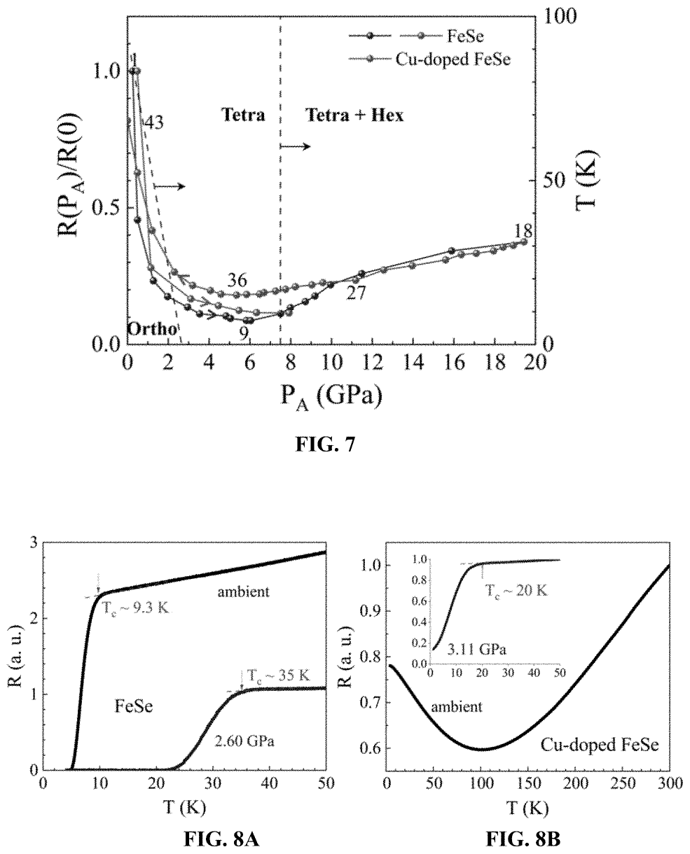

FIG. 7 is a plot illustrating R(P_{A})/R(0) of FeSe and Cu-doped FeSe single crystals at 300 K during pressure cycling. Dashed lines represent preliminary phase boundaries for FeSe. Numbers denote the sequential order of the experimental runs at different pressures.

FIGS. 8A-8B are plots illustrating resistance as a function of temperature for FeSe and Cu-doped FeSe single crystals, respectively. Red dashed lines and arrows define the value of T_{c} as the onset of superconductivity. FIG. 8A shows FeSe at ambient pressure (black) and at 2.60 GPa (blue). FIG. 8B shows Cu-doped FeSe at ambient pressure and (inset) at 3.11 GPa.

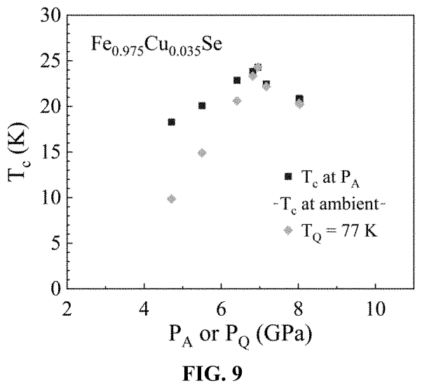

FIG. 9 is a plot illustrating T_{c} as a function of P_{A} or P_{Q} for single-crystalline Cu-doped FeSe. High-pressure T_{c} (P_{A}) at P_{A} (squares); and T_{c} (P_{Q}) at ambient pressure for Cu-doped FeSe sample PQed at P_{Q} and T_{Q}=77 K (diamonds).

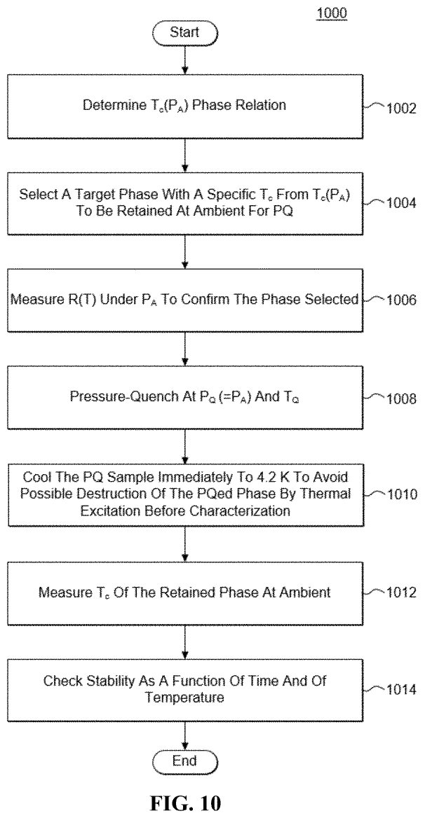

FIG. 10 is a flowchart illustrating an embodiment of a method of fabricating a superconductor. Included are the sequential PQP steps to obtain, test, and characterize the high T_{c} phase at ambient.

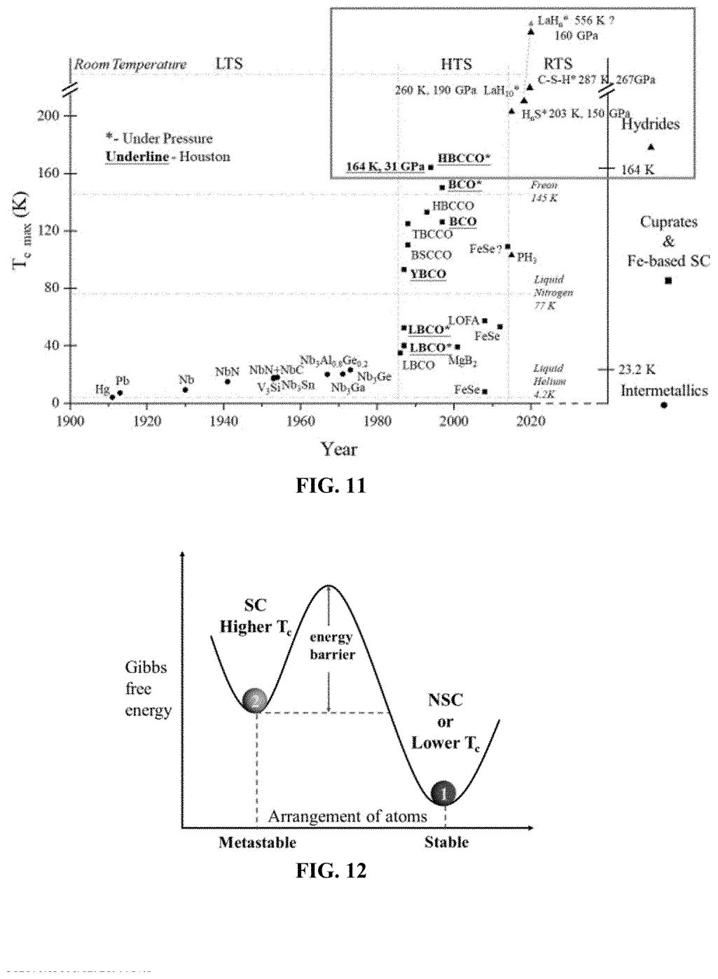

FIG. 11 is a plot illustrating record (highest reported) T_{c} as a function of time. Embodiments in this disclosure may apply to any of the HTS or RTS compositions shown in this figure, and may apply to other HTS or RTS compositions not shown in this figure.

FIG. 12 is a plot illustrating Gibbs free energy and the energy barrier between a superconducting (SC) state with a higher T_{c} and a non-SC state or a SC state with a lower T_{c}, demonstrating an approach to capture the “supercool” state via pressure-quench. More specifically, the figure shows schematic diagram of Gibbs free energy and the energy barrier between the metastable and stable states. The key steps for pressure-quenching. The figure illustrates pressure-quenching used to capture the “supercool” state or “metastable” state, without pressure (i.e., at ambient). The steps include: 1) Applying a chosen pressure P_{A} to a solid to induce or enhance the SC phase with a T_{c} desired; and 2) Remove the P_{A} completely and rapidly at a chosen T_{Q}.

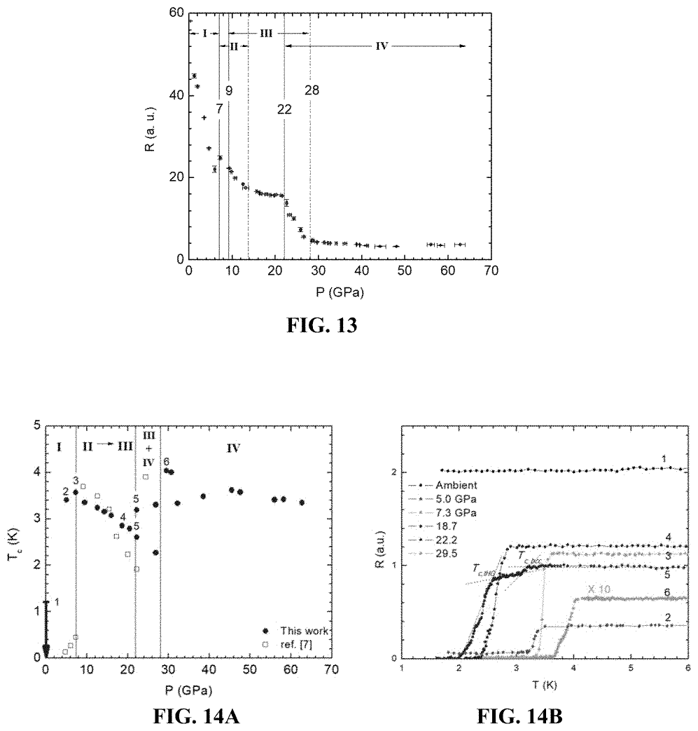

FIGS. 13-16B relate to pressure-induced superconductivity retained at ambient pressure in non-superconducting element Sb (single crystal). FIG. 13 is a plot illustrating pressure dependence of resistance at room temperature for four different structure phases I-IV of Sb: I—rhombohedral phase; II—monoclinic host-guest phase; III—tetragonal host-guest phase; and IV—bcc phase. The x-axis error bars reflect the pressure change before and after resistance measurements. The y-axis error bars indicate the resistance drifting range during data collection (Each point taken over at least 30 minutes). Vertical lines designate the pressure ranges for different phases.

FIGS. 14A-14B are plots illustrating the onset T_{c}s at different pressures for four different phases I-IV of Sb. FIG. 14A shows pressure dependence of onset T_{c}. Solid circles represent this work and open squares represent a reference. The low temperature R(T)s are plotted with numbers referred in FIG. 14B. Note that curve 5 (see FIG. 14B) shows two transitions indicating the sample is in the two-phase region of III and IV; curve 6 is enlarged by ten times for clarity due to small R of phase IV; and curve 2 shows a non-zero resistance suggesting a mixture of phases I and II.

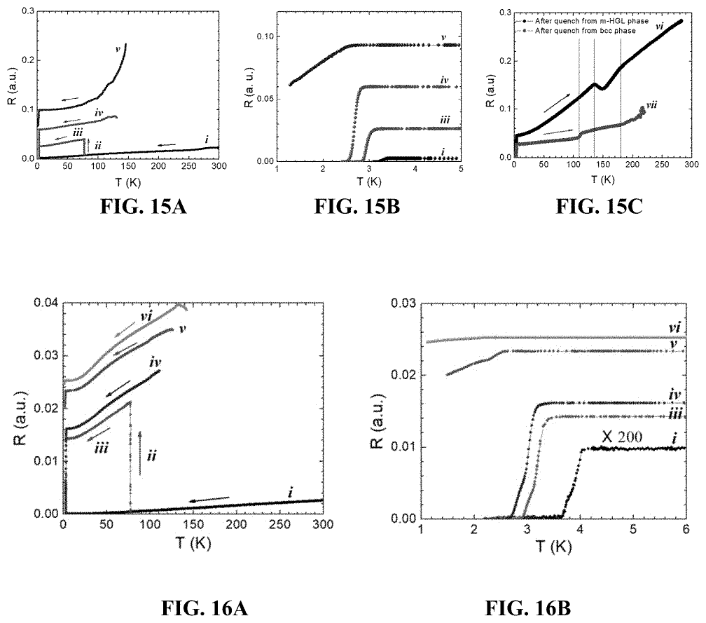

FIGS. 15A-15C are plots illustrating resistance versus temperature for Phase II (and IV in FIG. 15C) of Sb single crystal during PQP. FIG. 15A shows R(T)s: i—cooling from room temperature under 10.9 GPa; ii and iii—pressure quenched at 77 K and subsequence cooling; and iv and v—cooling from 131 K and 145 K, consecutively. FIG. 15B shows R(T)s at low temperature in an extended scale. FIG. 15C shows R(T)s: vi and vii were measured during warming after pressure-quenching from 9.2 GPa and 30.7 GPa, respectively.

FIGS. 16A-16B are plots illustrating resistance versus temperature for Phase IV. FIG. 16A shows R(T)s: i: cooling from room temperature under 29.5 GPa; ii and iii: pressure quenched at 77 K and subsequence cooling; iv, v and vi: cooling from 111 K, 126 K and 142 K, consecutively. FIG. 16b shows low temperature R at an expanded scale.

A pressure-quench technique at chosen pressures and temperatures to lock in the high-pressure-induced superconducting and/or non-superconducting phases in HTSs and RTSs at ambient pressure, removing the formidable obstacle to the ubiquitous practical application of HTS and RTS. The inventors are the first to deploy such a technique successfully in order to retain the high-pressure-induced/-enhanced high Tc and/or non-superconducting properties of HTS or RTS.

### Pressure-Induced High-Temperature Superconductivity Retained at Ambient in FeSe Single Crystals

As mentioned in the Background section above, the desire to raise the superconducting-transition temperature (T_{c}) has been the driving force for the long-sustained effort in superconductivity research. Recent progress in hydrides with T_{c}s up to 287 K under the pressure of 267 GPa has heralded a new era of room-temperature superconductivity (RTS) with immense technological promise. Indeed, RTS will lift the temperature barrier for the ubiquitous application of superconductivity. Unfortunately, formidable pressure is required to attain such high T_{c}s. The most effective relief to this impasse is to remove the pressure needed while retaining the pressure-induced T_{c} at ambient. This disclosure describes such a possibility in the pure and doped high-temperature superconductor (HTS) FeSe by retaining, at ambient pressure via pressure-quenching (PQ), its T_{c} up to 37 K (quadrupling that of a pristine FeSe at ambient) and other pressure-induced phases such as the non-superconducting hexagonal phase under pressure above 8 GPa. The inventors have also observed that some phases remain stable at ambient at up to 300 K and for at least 7 days. The observations are in qualitative agreement with our ab initio simulations using the solid-state nudged elastic band (SSNEB) method. The PQ technique developed here can be adapted to the RTS hydrides and other materials of value (such as Skyrmion materials, etc.).

### Significance

As RTS has been reported recently in hydrides at megabar pressures, the grand challenge in superconductivity research and development is no longer restricted to further increasing the superconducting transition temperature under extreme conditions and must now include concentrated efforts to lower, and considerably better yet remove, the applied pressure required. This work addresses directly such a challenge by demonstrating for the first time the inventors' successful retention of pressure-enhanced and/or -induced superconducting phases and/or non-superconducting phases (such as the hexagonal phase of FeSe induced at pressures above 8 GPa at ambient in single crystals of superconducting FeSe and non-superconducting Cu-doped FeSe. The pressure-quenching technique described in this disclosure offers the possibility of future practical application and the unraveling of RTS recently detected in hydrides but only under high pressures.

### Introduction

Recent reports show that RTS is indeed within reach, although only under high pressure (HP). For instance, T_{c}s above 200 K have been reported in unstable molecular solids (hydrides), i.e., up to 203 K in H₃S under 155 GPa, up to 260 K in LaH₁₀ under 190 GPa, up to 287 K in C—H—S under 267 GPa, and potentially well above room-temperature in La—H under 158 GPa after thermal cycling; earlier, T_{c} up to 164 K was reported in the stable cuprate HTS HgBa₂Ca₂Cu₃O_{8+δ} under 31 GPa. While record-high T_{c}s reported to date fall into practical cryogenic regimes for applications, the HP required to attain these superconducting states renders them impractical for significant applications or for scientific inquiries. The challenge is not restricted to further increasing the superconducting transition temperature under extreme conditions and must now include concentrated efforts to lower, and better yet remove, the applied pressure (P_{A}) required. Retaining the pressure-enhanced or -induced high-T_{c} superconducting (SC) phase at ambient will effectively meet this challenge.

FIG. 1A is a schematic diagram illustrating Gibbs free energy and the energy barrier between the metastable and stable states. FIG. 1B is a schematic diagram illustrating the sequence of main experimental steps, in accordance with an example of an embodiment.

It was pointed out in the 1950s that most of the alloys used in industrial applications are actually metastable at room temperature and atmospheric pressure. These metastable phases possess desired and/or enhanced properties that their stable counterparts lack. Examples include diamond and other super-hard materials, heavily doped semiconducting materials, certain 3D-printed materials, highly polymeric materials, black phosphorus, etc. They are metastable because they are kinetically stable but thermodynamically not, protected only by an energy barrier (FIG. 1A). By taking advantage of such energy barriers, lattice and/or electronic, one may therefore be able to stabilize the metastable phase or the “supercooled” state at atmospheric pressure via rapid pressure- and/or temperature-quenching. The energy barrier may be fortified by chemical doping; ionic liquid gating; a proper thermodynamic path; and introduction of strains, defects, or pressure inhomogeneity. The pressure-enhanced or -induced SC phase with a high T_{c} may be considered metastable or supercooled and may be stabilized. This disclosure describes the first successful retention of pressure-enhanced and -induced SC phases at ambient pressure in the Fe-based HTSs via PQ (FIG. 1B) at a chosen quench-pressure (P_{Q}) and quench-temperature (T_{Q}). P_{Q} is the pressure from which the pressure is rapidly removed to ambient. T_{Q} is the temperature at which the pressure is removed and it remains unchanged during the PQ process. The inventors have successfully retained a pressure-enhanced SC phase with a T_{c} up to 37 K at P_{Q}=4.15 GPa and T_{Q}=4.2 K in the SC FeSe and a pressure-induced SC phase with a T_{c} up to 26.5 K at P_{Q}=6.32 GPa and T_{Q}=4.2 K in the non-SC Cu-doped FeSe. The inventors have also retained the non-superconducting phase (the hexagonal phase) induced by pressure above ˜9 GPa in both samples via PQ. The pressure-quenched (PQed) high-T_{c} phases have also been found to be stable up to ˜200 K and for at least 7 days. Our observations have thus demonstrated that the pressure-enhanced or -induced high-T_{c} phases in HTSs can be retained at ambient pressure via PQ at a chosen P_{Q} and T_{Q}, suggesting a realistic path to the ubiquitous applications of the recently reported RTS.

### Results and Discussion

### Why FeSe was Chosen to Demonstrate PQP

In the present study, the inventors have chosen single crystals of the SC FeSe and the non-SC Cu-doped FeSe as model HTSs due to their simple structure and chemistry, as well as their large T_{c} variation under pressure and their important role in unraveling HTS. Furthermore, the iron-chalcogenide superconductors have attracted broad interest for applications from high-field magnets to quantum information science. For example, the Majorana zero modes reported in iron-chalcogenide superconductors can potentially be used for building topological qubits. The normalized resistance of FeSe and Cu-doped FeSe at 300 K as a function of pressure: R(P_{A})/R(0) during pressure-increasing and -decreasing is displayed in FIG. 7, which shows a clear hysteresis, suggesting that PQ may be possible since thermal hysteresis may provide the energy barrier (FIG. 1A) to retain the HP-induced phases. Preliminary boundaries of the orthorhombic (O) —tetragonal (T) —hexagonal (H) phase transitions of FeSe previously reported are also shown for later discussion. The T-O transition is suppressed from ˜90 K at ambient pressure to below 4.2 K at ˜2 GPa, as indicated by the dashed line at left in the same figure. At ambient pressure, R(T) of FeSe shows a sharp SC transition at 9.3 K (FIG. 8). The transition broadens under pressure, so the T_{c}(P) cited hereafter refers to the onset temperature as defined in FIG. 8. FIG. 2A (squares) displays the T_{c}-variation of FeSe with P_{A}: it increases slowly from ˜9 K at ambient pressure to ˜15 K below 1.9 GPa; suddenly jumps to ˜32 K at 1.9 GPa, coinciding with the O-T transition; continues to rise with a broad peak at ˜40 K around 4 GPa; but finally becomes insulating above ˜8 GPa as the H phase sets in.

### Discussion to Demonstrate What is PQP and how PQP Works

To retain at ambient pressure the above pressure-enhanced T_{c} of FeSe, the inventors have developed a technique to PQ the sample at different P_{Q}s and T_{Q}s by rapidly removing the P_{A}, under which a desired T_{c} has been first attained, from the sample in the diamond anvil cell (DAC), as shown in FIGS. 3A-3F. The temperature-dependent resistance of FeSe at different P_{A}s normalized to those at 70 K, R(T,P_{A})/R(70 K,P_{A}), near the superconducting transitions are exemplified in FIGS. 3A-3B for P_{A}s=4.15 GPa (close to maximum T_{c}˜40 K in the tetragonal phase), and 11.27 GPa (non-SC in the hexagonal phase), respectively. By following different thermal and pressure protocols as specified in the captions, they demonstrate the generation or destruction of the HP SC phase at P_{A} (blue), the retention at ambient pressure of the PQed (at 4.2 K) HP SC phase (red), and the thermal annealing effect up to 300 K on the PQed (at 4.2 K) HP phase to ascertain its retention (orange), all carried out sequentially.

As is evident from FIG. 3A, the T_{c} of the FeSe sample has been enhanced from ˜9 K at ambient pressure to ˜39 K under 4.15 GPa (blue). After PQ at 4.15 GPa and 4.2 K, a SC transition with a T_{c}˜37 K is detected at ambient pressure (red). To show that the 37 K-T_{c} is indeed attained by PQ, the inventors heated the sample up to 300 K before cooling it back down to 4.2 K and found that the PQed SC transition at 37 K is annealed away and replaced by its pre-PQed one, although at a higher T_{c}˜20 K (orange) rather than ˜9 K, presumably because of an unknown irreversible residual strain effect in the sample. FIG. 3B shows that FeSe at 11.27 GPa displays a non-SC transition as expected (blue), as does the PQed sample (red). However, the sample regains its SC transition with a T_{c}˜20 K after the PQed phase is annealed off after being heated up to 300 K (orange). To demonstrate the metastability of the PQed SC phases, the SC transition PQed at P_{Q}=4.13 GPa and T_{Q}=4.2 K upon sequential thermal cycling to higher temperatures is shown in FIG. 3C. The transition smoothly shifts downward and becomes sharper due to possible reduced fluctuations at lower temperature and/or the possible improved strain condition of the sample upon thermal annealing at higher temperatures. The sudden downward shift in the overall SC transition by ˜10 K after heating up to ˜200 K implies that the PQed phase transforms to the pre-PQed FeSe phase (with strain) and is stable up to 200 K. All T_{c}s of the PQed phases examined at different P_{Q}s and T_{Q}=4.2 K are summarized in FIG. 2A (circles).

As mentioned earlier, the PQed phase is metastable, and thus should depend on P_{Q} and T_{Q} and detailed electronic and phonon energy spectra of the materials examined. The inventors have therefore repeated the PQ experiments on FeSe by raising only the T_{Q} to 77 K (FIGS. 3D-3F). FIG. 3D shows that the T_{c} of FeSe before PQ has been enhanced to ˜37 K at 5.22 GPa (blue); upon PQ, a T_{c}˜24 K is retained at ambient pressure (green) in contrast to the 37 K when T_{Q}=4.2 K, as shown in FIG. 3A; and the transition returns to ˜14 K on cooling after warming to 300 K, showing that the 24 K transition is associated with the PQed phase. FIG. 3E shows that FeSe becomes insulating at 11.12 GPa (blue); the phase is retained at ambient pressure by PQ (green); and the PQed phase remains after heating to 300 K, suggesting that this PQed non-SC phase is stable up to 300 K. The effect of systematic thermal cycling with increasing temperatures on the PQed phase at P_{Q}=5.22 GPa and T_{Q}=77 K is shown in FIG. 3F. All T_{c}s of the PQ phases examined at different P_{Q}S and T_{Q}=77 K are also summarized in FIG. 2A (diamonds). They are all lower than those quenched at various P_{Q} and T_{Q}=4.2 K in general agreement with the competition between the instability of the SC state and thermal excitation.

To demonstrate that the retained SC state after PQ in pure FeSe at ambient pressure is not associated with the superconductivity of the pristine FeSe at ambient pressure, the inventors have repeated the PQ experiment on two non-SC Cu-doped FeSe samples (Fe_{1.01-x}CuₓSe with x=0.03 and 0.035; the x=0.03 sample is discussed below unless otherwise noted). As shown in FIG. 8B, Cu-doped FeSe is not SC above 1.2 K below 1.2 GPa (19, 21). Under pressure (FIG. 4 (squares)), it abruptly becomes SC with a T_{c}˜20 K at 3.11 GPa (inset, FIG. 8B); T_{c} continues to increase with increasing P_{A} and peaks at ˜27 K under 6.23 GPa; and at 9.65 GPa, only trace superconductivity was detected down to 1.2 K. Following the same protocols as those for the pure FeSe, the inventors performed PQ on Cu-doped FeSe at different P_{Q}s and T_{Q}s, as exemplified by FIGS. 5A-5F. Two examples of R(T,P_{A})s/R(50 K,P_{A}) for Cu-doped FeSe are given in FIG. 5A for P_{A}s=6.32 GPa and 6.16 GPa (close to maximum T_{c}˜27 K) PQed at T_{Q}=4.2 K and 77 K, respectively; and in FIG. 5B for 9.65 GPa (non-SC) PQed at T_{Q}=77 K. As is evident from the R(T,P_{A})s/R(50 K,P_{A}) in FIG. 5A, P_{A}˜6 GPa has induced a SC state in the non-SC Cu-doped FeSe with a T_{c}˜26 K (navy and blue); this SC state has been PQed at P_{Q}=6.16 GPa and T_{Q}=4.2 K (red) and at P_{Q}=6.32 GPa and T_{Q}=77 K (green), respectively. Disappearance of the SC phase after thermal cycling up to 300 K (FIG. 5A, orange and brown) demonstrates that the SC states induced by P_{A}˜6 GPa have been retained at ambient pressure with T_{c}˜26 K via PQ at 4.2 K and 77 K, respectively. As shown in FIG. 5B, P_{A}=9.65 GPa turns the sample to an insulating state (blue); upon PQ at T_{Q}=77 K it remains insulating (green); and the sample stays in the non-SC state after thermal cycling to 300 K (orange), suggesting that the insulating state PQed at 9.65 GPa and 77 K is stable up to 300 K. The thermal stability ranges of the PQed SC states at P_{Q}=6.08 GPa and T_{Q}=4.2 K and at P_{Q}=5.95 GPa and T_{Q}=77 K are shown in FIGS. 5C-5D, respectively. They show that the state PQed at a lower T_{Q} possesses a wider thermal stability range. The anomalies observed in R(T) upon warming right after PQ (FIG. 5E) correlate qualitatively with the thermal stability of the PQed phases (FIGS. 5C-5D). FIG. 5F demonstrates that the PQed SC phase at P_{Q}=6.67 GPa and T_{Q}=77 K remains unchanged for at least 7 days after thermal cycling between 50 K and 4.2 K. All PQed T_{c}s of Cu-doped FeSe are summarized in FIG. 4. Unlike in their pristine unpressurized state, the two different Cu-doped FeSe samples both behave similarly to FeSe under pressures, but with their phase boundaries shifted to higher values, as displayed in FIG. 2, FIG. 4 and FIG. 9, due to the Cu-doping effect. While PQ works for both pure and Cu-doped FeSe in retaining at ambient the pressure-enhanced or -induced SC states, the effect of T_{Q} on the T_{c} of the PQed SC phase for Cu-doped FeSe is smaller than that for FeSe, due to the possible change in the electronic structure resulting from doping. This suggests that doping can help adjust the PQ parameters.

To gain a better understanding of the PQ effects on FeSe, the inventors performed ab initio simulations to evaluate the phase transition energy barriers between different phases via solid-state nudged elastic band (SSNEB). As shown in FIGS. 6A-6B, the phase transition energy barrier between the orthorhombic and tetragonal phases is small. For instance, the energy barrier is 3 meV/atom at 6 GPa, which is lower than the energy barrier of 6 meV/atom at 0 GPa, suggesting that the transition temperature between these two phases at HP should be lower than that at ambient pressure, in agreement with the experimental observations. Nevertheless, the small energy barrier between those two structures ensures that FeSe could preserve the structure phase from one transfer to the other when PQed from above 2 GPa to ambient pressure at low temperatures, as well as the superconductivity. On the other hand, the phase transition energy barrier from the hexagonal to the tetragonal phase is significantly larger, about 0.189 and 0.193 eV/atom at 8 and 11 GPa, respectively (FIGS. 6C-6D). The inventors also noticed that the tetragonal phase is energetically more favorable than the hexagonal phase at simulated pressures. The phase transition between the tetragonal and hexagonal phases will occur at 15 GPa based on our simulation, in agreement with previous calculations. The estimated energy barriers are comparable to that between graphite and cubic diamond, around 0.21 eV/atom at 10 GPa, suggesting that the hexagonal phase could be preserved during the quenching process once it is formed, as the inventors observed in the experiments. The energy barrier is high enough to prevent FeSe returning to the orthorhombic phase from the hexagonal phase at ambient pressure and 300 K, which is consistent with our experiments at P_{Q}=11.12 GPa and T_{Q}=77 K shown in FIG. 3E.

### Conclusions

The inventors have demonstrated that the pressure-enhanced or -induced superconducting phases with high T_{c} and the pressure-induced non-superconducting phases in FeSe and Cu-doped FeSe can be stabilized at ambient by pressure-quenching at chosen pressures and temperatures. More generally, the breakthrough that the inventors found for RTS includes removing the pressure and retaining the high T_{c} at ambient by Pressure-Quench at a chosen quench-pressure P_{Q} and quench-temperature T_{Q}. These pressure-quenched phases have been shown to be stable at up to 300 K and for up to at least 7 days depending on the quenching conditions. The observations raise the hope that the recently reported RTS in hydrides close to 300 GPa may be retained at ambient, making possible the ubiquitous applications of RTS envisioned.

### Materials and Methods

### Sample Preparation

Single crystals of Fe_{1.01-x}CuₓSe (x=0, 0.03, and 0.035) were grown using the chemical vapor transport (CVT) method. Stoichiometric Fe (99.9%, Alfa Aesar), Cu (99.9%, Alfa Aesar), and Se (99.5%, Alfa Aesar) powders were thoroughly mixed and loaded into a quartz tube. AlCl₃ (99%, Alfa Aesar) and KCl (99%, Alfa Aesar) powders were added as the transport agents. After the evacuated quartz tube was sealed, it was placed into a two-zone tube furnace, in which the temperatures of the hot and cold positions were maintained at 420° C. and 330° C., respectively. After 20 days, single crystals with an average size of 3×3×0.1 mm³ were grown around the region of the quartz tube's cold zone. Chemical composition was determined by energy-dispersive spectroscopy (EDS) using a Tescan Lyra scanning electron microscope (SEM) equipped with an EDS detector (Oxford Instruments). The compositions for Cu-doped FeSe single crystals were determined to be Fe_{0.98}Cu_{0.03}Se and Fe_{0.975}Cu_{0.035}Se.

### Electrical Transport Measurements Under Pressure

For resistivity measurements conducted in this investigation, pressure was applied to the samples using a Mao-type symmetric diamond anvil cell with a culet size of 500 μm. The gaskets are made from T301 half-hard stainless-steel sheets with thickness of 300 μm. Each gasket was preindented to ˜20-40 μm in thickness and was insulated with Stycast 2850FT. The sample's chamber diameter is 250 μm, where either sodium chloride or cubic boron nitride is used as the pressure-transmitting medium. Samples were cleaved and cut into thin squares with a diagonal of ˜200 μm and thickness of ˜10 μm. The pressure was determined using the ruby fluorescence scale or the diamond Raman scale at room temperature. The samples' contacts were arranged in a Van der Pauw configuration and data were collected using a Keithley 2182A/6221 low-resistance measurement setup. Measurements were conducted in a homemade cooling system that can be cooled to 1.2 K by pumping on the liquid-helium space. Pressure-quenching was performed by releasing the screws at target temperatures down to 4.2 K with a small residual pressure P_{R}<0.2 GPa to maintain the electrical connectivity for resistivity measurements, and the P_{R} was measured at room temperature.

### Theoretical Calculations

The calculations were performed within the framework of density functional theory via the generalized gradient approximation GGA+U method implemented in the Vienna ab initio simulation package (VASP). The electron-ion interactions were represented by means of the all-electron projector augmented wave (PAW) method, where 3d⁶4s² and 4s²4p⁴ are treated as the valence electrons for Fe and Se, respectively. The inventors used the Dudarev implementation with on-site coulomb interaction U=5.0 eV and on-site exchange interaction J=0.8 eV to treat the localized 3d electron states. The Perdew-Burke-Ernzerhof (PBE) function in the generalized gradient approximation (GGA) was used to describe the exchange-correlation potential. The plane-wave energy cutoff of 400 eV and a dense k-point grid of spacing 2π×0.03 Å⁻¹ in the Monkhorst-Pack scheme were used to sample the Brillouin zone. Structural relaxations were performed with forces converged to less than 0.05 eV Å¹. To determine the energy barriers, the inventors used the solid-state nudged elastic band method (SSNEB) (28) implemented in VASP. The NEB path was first constructed by linear interpolation of the atomic coordinates and then relaxed until the forces on all atoms were <0.05 eV/Å.

The pressure-enhanced or -induced superconducting phase with a high T_{c} in a superconductor or a non-superconductor may be considered metastable or “supercooled” and may be retained at ambient pressure following a certain thermodynamic path. The retention of the metastable state with a desired T_{c} at ambient pressure has been demonstrated by deploying PQP in non-superconducting elements Sb and Bi, superconducting FeSe, and non-superconducting Cu-doped FeSe at specific P_{Q}s and T_{Q}s in accordance with the sequential steps set forth in FIG. 10 which is a flowchart illustrating an embodiment of a method 1000 of fabricating a superconductor. The method 1000 includes the sequential PQP steps to obtain, test, and characterize the high T_{c} phase at ambient. Specifically, the method 1000 includes determining the dependence of T_{c} on the applied pressure P_{A}, T_{c}(P_{A}) (block 1002); select the high-pressure superconducting phase with a specific T_{c} from T_{c}(P_{A}) to be retained at ambient (block 1004); apply a pressure P_{A} to the material to generate the selected superconducting phase (block 1006); PQ the selected superconducting phase by rapidly reducing P_{A} (also known as P_{Q}) at a T_{Q} to close to ambient (i.e., between 0.0001 GPa to 0.1 GPa) with a negligible residual value (0.001 GPa to 0.1 GPa) to maintain the integrity of the electrical leads for characterization (block 1008); cool the PQ sample immediately to 4.2 K to avoid possible destruction of the PQed phase by thermal excitation before characterization (block 1010); measure the sample resistance on warming from 4.2 K until the superconducting transition is completed to ascertain that the selected high-pressure superconducting phase has been achieved at ambient via PQP and at a much higher T_{c} than that before being PQed (block 1012); check stability as a function of time and of temperature (block 1014); and further test whether the PQed superconducting phase is indeed the metastable phase PQed by warming the sample to 300 K (or to higher temperature for RTS) and confirming that it no longer displays the high T_{c} transition (this step is optional).

Embodiments are directed to a method for retaining a high-pressure-induced superconducting or non-superconducting phase in a high-temperature superconductor HTS (with a T_{c} between 20 K and 160 K) or a RTS (with a T_{c} above 160 K), at ambient or atmospheric pressure. In other words, an embodiment retains (either) a superconducting or non-superconducting phase in a HTS. Or, another embodiment retains (either) a superconducting or non-superconducting phase in a RTS. And any/all of the above phase scenarios are being retained at ambient pressure. The method includes: generating a superconducting or non-superconducting phase in a HTS or RTS by applying a pressure at room temperature thereby producing a superconducting phase with a particular T_{c} or a non-superconducting phase in the HTS or RTS; pressure-quenching the HTS or RTS from the generating step while under the pressure at room temperature, by subsequently removing the pressure to achieve ambient pressure at a temperature lower than 300 K, while maintaining the superconducting phase with the particular T_{c} or the non-superconducting phase in the HTS or RTS; and retaining the superconducting or non-superconducting phase in the HTS or RTS while maintaining the superconducting phase with the particular T_{c} or the non-superconducting phase in the HTS or RTS, at ambient pressure, subsequent to the pressure-quenching step.

In an embodiment, the pressure removal is performed in less than 10.0 seconds, and preferably in the range of 0.01-10.0 seconds and at a temperature below 300 K, and more preferably in the range of 0.01-1.0 second at a temperature below 300 K.

In an embodiment, the pressure applied at room temperature is in the range of 0.1 GPa to 300 GPa.

In an embodiment, the HTS comprises a T_{c} between 20 K and 160 K, and the RTS comprises a T_{c} above 160 K.

In an embodiment, the HTS comprises FeSe.

In an embodiment, the HTS comprises Cu-doped FeSe.

In an embodiment, the RTS comprises a hydride.

In an embodiment, the RTS comprises H₃S.

In an embodiment, the RTS comprises LaH₁₀.

In an embodiment, a HTS or a RTS having the superconducting phase with the particular T_{c} or non-superconducting phase in the HTS or RTS is retained at ambient pressure via the method of claim 1.

Embodiments are also directed to a HTS or a RTS having a superconducting phase with a particular T_{c} or non-superconducting phase in the HTS or RTS induced via an applied pressure at room temperature and retained at ambient pressure.

### Example Embodiments

The following examples illustrate successful demonstrations of the pressure-quenching (PQ) technique on single crystals of non-SC element Sb and HTS SC FeSe and non-SC Cu—FeSe. The technique stabilizes at ambient the high-pressure-induced/enhanced high T_{c} SC and the non-SC states.

Example 1: for the retention of the pressure-enhanced superconducting phase in HTS.-FeSe Has a T_{c} of 9 K. Under a pressure between 2 and 8 GPa, a superconducting phase with a T_{c} up to 40 K can be achieved; upon the removal of pressure at 4.2 K in the range of 0.01-10.0 second; phases with a T_{c} between 30 K and 38 K are retained.

Example 2: for the retention of the pressure-enhanced superconducting phase in HTS.-FeSe Has a T_{c} of 9 K. Under a pressure between 2 and 8 GPa, a superconducting phase with a T_{c} up to 40 K can be achieved; upon the removal of pressure at 77 K in the range of 0.01-10.0 second, phases with a T_{c} between 12 K and 24 K are retained.

Example 3: for the creation and the retention of the high-pressure-induced non-superconducting phase in HTS-FeSe becomes non-superconducting above 8 GPa; upon the removal of pressure in the range of 0.01-10.0 second below 300 K, the non-superconducting phase is retained.

Example 4: for the creation and retention of the high-pressure-induced superconducting phase in the non-superconducting Cu-doped FeSe-Cu-doped FeSe is not superconducting and becomes superconducting between 3 and 9 GPa with a T_{c} up to 26 K; upon the removal of pressure below 300 K in the range of 0.01-10.0 second, the superconducting phases with a T_{c} between 12 K and 5 K are retained.

Example 5: for the creation and retention of the high-pressure induced non-superconducting phase in the non-superconducting Cu-doped FeSe-Cu-doped FeSe is not superconducting and becomes superconducting between 3 and 9 GPa with a T_{c} up to 26 K; becomes non-superconducting above 9 GPa; upon the removal of pressure below 300 K in the range of 0.01-10.0 second, the non-superconducting phase is retained.

Example 6: for the creation and retention of the high-pressure-induced phases in the non-superconducting RTS hydride-H₃S is not superconducting, under pressures above 150 GPa; becomes metallic and superconducting at 203 K; upon the rapid reduction of pressure to 100 GPa at or below 300 K in the range of 0.01-10.0 second, the superconducting phase with a T_{c} of 150 K can be retained.

Example 7: for the creation and retention of the high-pressure-induced phases in the non-superconducting RTS hydride-H₃S is not superconducting, under pressures above 150 GPa; becomes metallic and superconducting at 203 K; upon the reduction of pressure to 100 GPa at or below 300 K in 0.01-10.0 second, the superconducting phase with a T_{c} of 100 K can be retained.

Example 8: for the creation and retention of the high-pressure-induced phases in the non-superconducting RTS hydride-H₃S is not superconducting, under pressures above 75 GPa; becomes metallic and superconducting at 100 K; upon the removal of pressure at or below 300 K in 0.01-10.0 second, the superconducting phase with a T_{c} of 70 K can be retained.

Example 9: for the creation and retention of the high-pressure-induced superconducting phases in the non-superconducting RTS hydride-LaH₁₀ is not superconducting, under pressures above 190 GPa; becomes metallic and superconducting at 260 K; upon the reduction of pressure to 100 GPa at or below 300 K in 0.01-10.0 second followed by the removal of pressure, the superconducting phase with a lower T_{c} of e. g. 100 K can be retained.

Example 10: for the creation and retention of the high-pressure-induced phases in the non-superconducting RTS hydride-LaH₁₀ is not superconducting, under pressures above 190 GPa; becomes metallic and superconducting at 260K; upon the reduction of pressure to 100 GPa at or below 300 K in 0.01-10.0 second, the superconducting phase with a lower T_{c} of 200 K can be retained.

Example 11: for the creation and retention of the high-pressure-induced phases in the non-superconducting RTS hydride-LaH₁₀ is not superconducting, under pressures above 190 GPa; becomes metallic and superconducting at 260K; upon the reduction of pressure to 50 GPa at or below 300 K in 0.01-10.0 second, the superconducting phase with a T_{c} of. 150 K can be retained.

Example 12: for the creation and retention of the high-pressure-induced phases in the non-superconducting RTS hydride-LaH₁₀ is not superconducting, under pressures above 190 GPa; becomes metallic and superconducting at 260K; upon the removal of pressure at or below 300 K in 0.01-10.0 second, the superconducting phase with a lower T_{c} of 150 K can be retained.

Although embodiments are described above with reference to superconductor materials comprising single crystals of SC FeSe and non-SC Cu-doped FeSe as model HTSs, the superconductor materials described in any of the above embodiments may alternatively be superconductors comprising different superconductor material(s) such as those depicted in FIG. 11, and may be in single or polycrystalline form. Such alternatives are considered to be within the spirit and scope of the present invention, and may therefore utilize the advantages of the configurations and embodiments described above.

The method steps in any of the embodiments described herein are not restricted to being performed in any particular order. Also, structures mentioned in any of the method embodiments may utilize structures mentioned in any of the device embodiments. Such structures may be described in detail with respect to the device embodiments only but are applicable to any of the method embodiments. Further, phases mentioned in any of the method embodiments may utilize phases mentioned in any of the device embodiments. Such phases may be described in detail with respect to the device embodiments only but are applicable to any of the method embodiments.

Features in any of the embodiments described above may be employed in combination with features in other embodiments described above, such combinations are considered to be within the spirit and scope of the present invention.

The contemplated modifications and variations specifically mentioned above are considered to be within the spirit and scope of the present invention.

It's understood that the above description is intended to be illustrative, and not restrictive. The material has been presented to enable any person skilled in the art to make and use the concepts described herein, and is provided in the context of particular embodiments, variations of which will be readily apparent to those skilled in the art (e.g., some of the disclosed embodiments may be used in combination with each other). Many other embodiments will be apparent to those of skill in the art upon reviewing the above description. The scope of the embodiments herein therefore should be determined with reference to the appended claims, along with the full scope of equivalents to which such claims are entitled. In the appended claims, the terms “including” and “in which” are used as the plain-English equivalents of the respective terms “comprising” and “wherein.”

What is claimed is:

1. A method for retaining a high-pressure-induced superconducting phase or non-superconducting phase in a high-temperature superconductor (HTS) or a room-temperature superconductor (RTS), at ambient pressure, the method comprising:
generating a superconducting or non-superconducting phase in a HTS or RTS by applying a pressure at room temperature thereby producing a superconducting phase with a particular transition temperature (T_{c}) or a non-superconducting phase in the HTS or RTS;
pressure-quenching the HTS or RTS from the generating step while under the pressure applied at room temperature, by subsequently removing the applied pressure to achieve ambient pressure at a temperature lower than 300 K, while maintaining the superconducting phase with the particular T_{c} or the non-superconducting phase in the HTS or RTS; and
retaining the superconducting or non-superconducting phase in the HTS or RTS while maintaining the superconducting phase with the particular T_{c} or the non-superconducting phase in the HTS or RTS, at ambient pressure, subsequent to the pressure-quenching step.

2. The method of claim 1, wherein the pressure removal is performed in less than 10.0 seconds.

3. The method of claim 1, wherein the pressure applied at room temperature is in the range of 0.1 GPa to 300 GPa.

4. The method of claim 1, wherein the HTS comprises a T_{c} between 20 K and 160 K, and the RTS comprises a T_{c} above 160 K.

5. The method of claim 1, wherein the HTS comprises FeSe.

6. The method of claim 1, wherein the HTS comprises Cu-doped FeSe.

7. The method of claim 1, wherein the RTS comprises a hydride.

8. The method of claim 1, wherein the RTS comprises H₃S.

9. The method of claim 1, wherein the RTS comprises LaH₁₀.

10. A HTS or a RTS having the superconducting phase with the particular T_{c} or non-superconducting phase in the HTS or RTS retained at ambient pressure via the method of claim 1.

11. A high-temperature superconductor (HTS) or a room-temperature superconductor (RTS) having a superconducting phase with a particular transition temperature (T_{c}) or non-superconducting phase in the HTS or RTS induced via an applied pressure at room temperature and retained at ambient pressure.

12. The HTS or RTS of claim 11, wherein the transition from applied pressure to ambient pressure occurs in less than 10.0 seconds.

13. The HTS or RTS of claim 11, wherein the pressure applied at room temperature is in the range of 0.1 GPa to 300 GPa.

14. The HTS or RTS of claim 11, wherein the HTS comprises a T_{c} between 20 K and 160 K, and the RTS comprises a T_{c} above 160 K.

15. The HTS or RTS of claim 11, wherein the HTS comprises FeSe.

16. The HTS or RTS of claim 11, wherein the HTS comprises Cu-doped FeSe.

17. The HTS or RTS of claim 11, wherein the RTS comprises a hydride.

18. The HTS or RTS of claim 11, wherein the RTS comprises H₃S.

19. The HTS or RTS of claim 11, wherein the RTS comprises LaH₁₀.
